(19) United States
(12) Patent Application Publication
(10) Pub. No.: US 2011/0088771 A1
(43) Pub. Date: Apr. 21, 2011

(54) PROCESS OF MANUFACTURING TCO SUBSTRATE WITH LIGHT TRAPPING FEATURE AND THE DEVICE THEREOF

(75) Inventors: Yuting LIN, Taichung County (TW); Shihche HUANG, Chiayi City (TW); Wenkai HSU, Zhubei City (TW)

(73) Assignee: DU PONT APOLLO LTD., Hong Kong (HK)

(21) Appl. No.: 12/906,752

(22) Filed: Oct. 18, 2010

Related U.S. Application Data
(60) Provisional application No. 61/252,968, filed on Oct. 19, 2009.

(51) Int. Cl. H01L 31/0224; H05K 1/09; B22F 3/00; B05D 5/12; C23C 14/34; C23C 14/14; C25D 5/00

(52) U.S. Cl. 136/256; 174/257; 427/126.1; 427/123; 427/126.3; 204/192.1; 205/224; 205/170; 257/E31.126

(57) ABSTRACT

A new process of manufacturing a transparent conductive oxide (TCO) substrate with light trapping feature and the device thereof is described. The process comprises: forming a metal layer on a substrate, annealing the metal layer so that metal elements are self-aggregated, thereby forming a plurality of island-structure metal protrusions; and forming a transparent conductive oxide layer on the island-structure metal protrusions and the substrate.

### FIELD OF THE INVENTION

The present invention relates to the field of thin film solar cells. Particularly, the present invention discloses a process of manufacturing a transparent conductive oxide (TCO) substrate with light trapping feature.

### BACKGROUND OF THE INVENTION

Transparent conductive oxides (TCO) are necessary as front electrodes for most thin film solar cells. They provide low electrical and optical losses and additional optical functions like light scattering. In an ideal case, the scattered light is confined within the multilayered thin film solar cell (this phenomenon is called light trapping) and almost completely absorbed. Particularly, silicon solar cells rely on effective light trapping. One way to improve the efficiency of thin film solar cells is to increase the light trapping phenomenon in the TCO layer. Usually, the surface of the TCO layer having random surface texture or roughness can allow more scattering of light in the TCO layer and thus increase light trapping.

Currently, there are two common ways to control the surface structure of the TCO layer for increasing light trapping. The first one utilizes a method of Atmospheric Pressure Chemical Vapor Deposition (APCVD) to deposit materials on the substrate to grow a TCO layer with a tetrahedron-like or pyramid-like textured surface. Please refer to FIG. 1 which is a SEM (scanning electron microscope) image which shows the surface of the TCO layer made by APCVD method. This method is controlled by changing the parameters such as the gas species, gas flow rate, temperature, and so on to deposit a surface with protrusions of different sizes, as shown in FIG. 1.

Owing to the high cost of the method of APCVD, the other method, wet etching, has gotten more attention. Please refer to FIG. 2 which shows a SEM image for the surface of the TCO layer made by wet etching method. A surface with rough pits is obtained by a wet etching method. Contrary to the APCVD, the surface structure is etched from up to down. By controlling the parameters of wet etching, such as the concentration of the etching solution and the etching time, different extents of roughness on the surface can be achieved, thereby obtaining different properties of the etched film, such as transmittance diffusion or transmittance, haze and so on. The degree of surface roughness will lead to different degrees of light trapping phenomenon. In particular, the etching solution with stable concentration is very important to the control of the degree of surface roughness. However, in big scale commercial production, it is hard to keep etching solution in a stable concentration. Thus, the results of the products are difficult to be reproducible.

Thus, although the TCO layer with light trapping feature can be achieved by the two above-mentioned methods, it is necessary to provide a simple, cheap, highly reproducible process for manufacturing a light trapping TCO substrate.

### SUMMARY OF THE INVENTION

In view of the problems described, the present invention provides a process of manufacturing a transparent conductive oxide (TCO) substrate with light trapping feature comprising:
forming a metal layer on a substrate,
annealing the metal layer so that metal elements of the metal layer are self-aggregated, thereby forming a plurality of island-structure metal protrusions; and
forming a transparent conductive oxide layer on the island-structure metal protrusions and the substrate.

The present invention also provides a TCO substrate with light trapping feature comprising:
a substrate;
a plurality of island-structure metal protrusions, formed on the substrate; and
a TCO layer, formed on the substrate and the island-structure metal protrusions.

### BRIEF DESCRIPTION OF THE DRAWING

FIG. 1 is a SEM image which shows the surface of the TCO layer made by APCVD method.

FIG. 2 is a SEM image which shows the surface of the TCO layer made by wet etching method.

FIG. 3 shows that the self-aggregate property of aluminum at high temperature would form island-structure aluminum protrusions.

FIG. 4 is a schematic cross-sectional view which shows the smooth shape of the TCO formed by sputtering or evaporation method.

FIG. 5 is a schematic cross sectional view which shows the saw-toothed shape of the TCO formed by chemical vapor deposition (CVD).

FIG. 6 is a schematic view depicting the steps in a process for manufacturing a TCO substrate of an embodiment of the present invention.

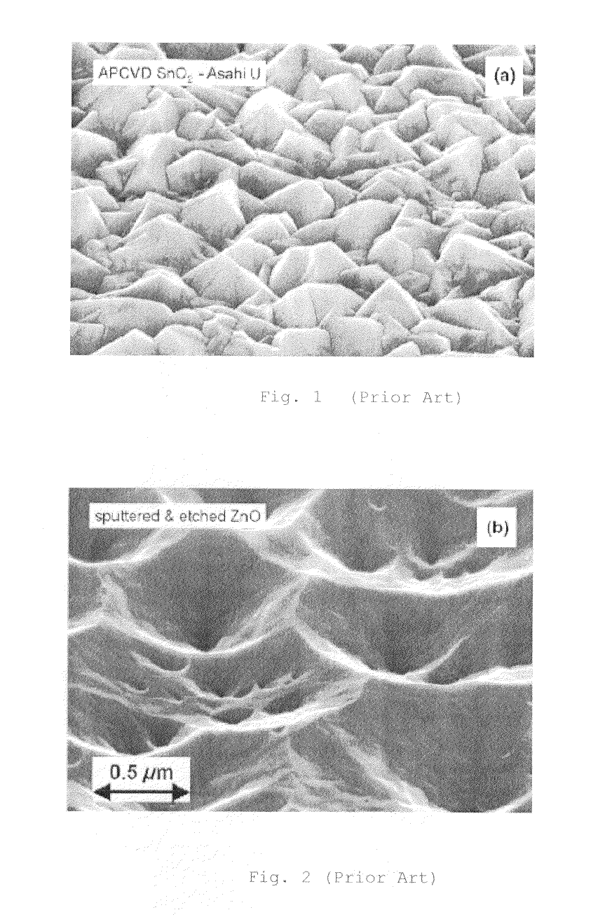

### DETAILED DESCRIPTION OF THE INVENTION

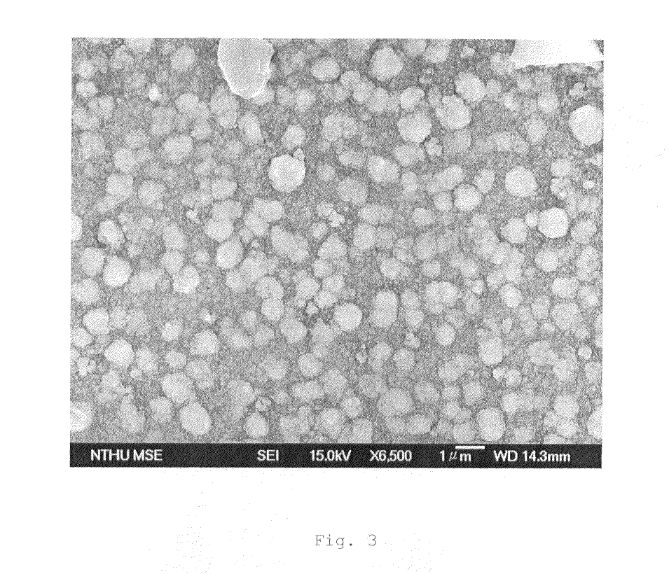

The present invention provides a process of manufacturing a transparent conductive oxide substrate with light trapping feature by utilizing the self-aggregated property of metal elements at high temperature. Specifically, raising the temperature to near the melting point of metal would anneal metal so that the annealed metal self-aggregates and forms island structures (FIG. 3). The needed temperature has to be slightly lower than the melting point of the metal, but cannot be below the melting point more than 150° C. (mp 150° C.≦t<mp). Preferably, mp−100° C.≦t<mp. The selected metal layer preferably has a melting point lower than that of the substrate. Preferable, the melting point of the metal layer is below 800° C.

As an aspect of the present invention, the process can be conducted without any etching step and thus can replace the conventional APCVD or wet etching method. The TCO layer made by the present invention can increase the efficiency of the solar cell. In addition, the properties of the TCO layer are highly reproducible because there are fewer and simpler controlling parameters in the process.

The present invention provides a process of manufacturing a transparent conductive oxide substrate with light trapping feature comprising:
forming a metal layer on a substrate,
annealing the metal layer so that metal elements of the metal layer are self-aggregated, thereby forming a plurality of island-structure metal protrusions; and
forming a transparent conductive oxide on the island-structure metal protrusions and the substrate.

The metal layer can be formed by sputtering, evaporation, or electroplating method. The transparent conductive oxide can be formed by sputtering, chemical vapor deposition (CVD), or evaporation method.

The substrate may be glass or polyimide.

The melting point of the metal layer is lower than that of glass, preferably below 800 C. the material of the metal layer can be selected from the group consisting of Ag, Al, Cu, Cr, Zn, Mo, Ca, Ti, In, Sn, Ni, and combination thereof. Preferably, the material of the metal is Al.

The material of the transparent conductive oxide may be selected from the group consisting of ZnO, ZnO:Al (AZO), ZnO:Ga(GZO), SnO₂:Sb(ATO), SnO₂:F(FTO), In₂O₃:Sn(ITO), BaTiO and combination thereof. Preferably, the material of the transparent conductive oxide is ZnO or ZnO:Al (AZO).

The thickness of the transparent conductive oxide layer may range from 0.05 to 3 μm, preferably 0.1 to 2 μm. The thickness of the metal layer may range from 1 to 1000 nm, preferably 1 to 100 nm.

The process may further comprise a step of forming a barrier layer on the substrate before the step of forming the metal layer. The barrier layer can be formed by sputtering. The thickness of the barrier layer may range from 1 to 100 nm. The barrier layer is used to inhibit Na ion diffusion from the substrate to corrode TCO, thereby preventing TCO from peeling off the substrate. Preferably, the barrier layer is a SiO₂ layer.

As a further aspect of the present invention, because of the increase in light trapping, solar cells have higher efficiency by incorporating a transparent conductive oxide layer with light trapping feature manufactured by the process of the present invention.

The present invention also provides a TCO substrate with light trapping feature comprising:
a substrate;
a plurality of island-structure metal protrusions, formed on the substrate; and
a TCO layer, formed on the substrate and the island-structure metal protrusions.

In the TCO substrate, the island-structure metal protrusions are semi-spherical metal protrusions.

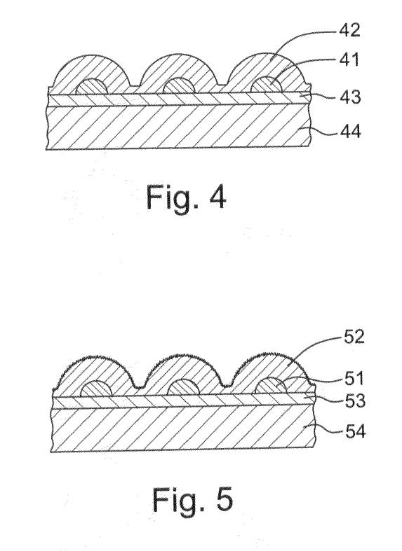

As shown in FIG. 4, by sputtering or chemical vapor deposition (CVD), the TCO layer 42 can be formed as a smooth layer on a substrate 44 (such as a glass substrate), optionally with a barrier layer 43 (such as a SiO₂ layer) on the substrate, and on the island-structure metal protrusions 41. As shown in FIG. 5, by evaporation method, the TCO layer 52 can be formed as a saw-toothed layer on a substrate 54 (such as a glass substrate), optionally with a barrier layer 53 (such as a SiO₂ layer) on the substrate, and on the island-structure metal protrusions 51.

As a further aspect of the present invention, a solar cell may comprise a TCO substrate with light trapping feature of present invention to achieve higher efficiency.

### EXAMPLE

An example of the present invention will be described. The example illustrates a preferable embodiment of the present invention, and the present invention is not limited to the example.

### Example 1

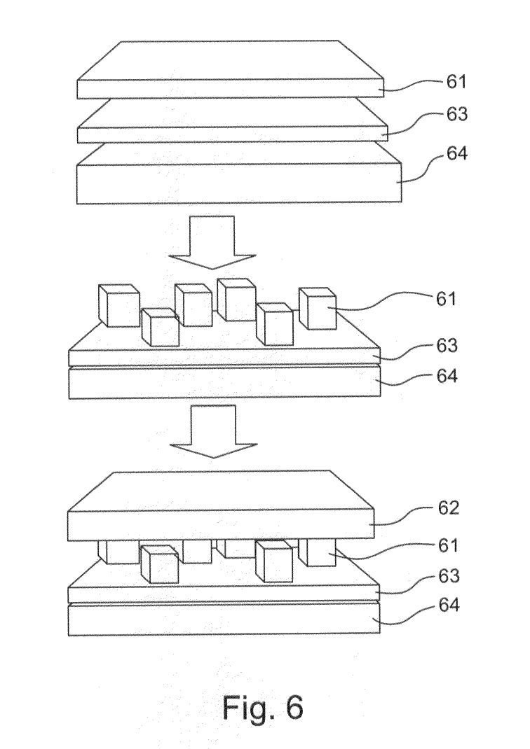

The process of manufacturing a TCO layer can be illustrated by FIG. 6. At first, a SiO₂ layer 63 of 10 nm was sputtered on a glass substrate 64 surface. Then an aluminum layer 61 about 5˜10 nm was sputtered on the SiO₂ layer. The aluminum layer is annealed by raising the temperature from 500° C. to 600° C., preferably to 550° C., in 30 minutes. At this situation, the metal element, i.e. Al, self-aggregates to form a plurality of island structure metal protrusions. Then, ZnO 62 is sputtered on the island structure metal protrusions and the SiO₂ layer to form a TCO layer of 0.6˜0.7 μm.

The invention is not limited to the embodiment described above, which is presented as an example only, and can be modified in various ways within the scope of protection defined by the appended patent claims.

What is claimed is:

1. A process of manufacturing a transparent conductive oxide (TCO) substrate with light trapping feature comprising:
forming a metal layer on a substrate;
annealing the metal layer so that metal elements of the metal layer are self-aggregated, thereby forming a plurality of island-structure metal protrusions; and
forming a transparent conductive oxide layer on the island-structure metal protrusions and the substrate.

2. The process of claim 1, wherein the metal layer is formed by sputtering, evaporation, or electroplating method.

3. The process of claim 1, wherein the transparent conductive oxide layer is formed by sputtering, chemical vapor deposition (CVD), or evaporation method.

4. The process of claim 1, wherein the metal layer is annealed at a temperature from mp−150° C.≦t<mp.

5. The process of claim 1, wherein the metal layer has a melting point lower than the melting point of the substrate.

6. The process of claim 1, wherein the metal layer has a melting point below 800° C.

7. The process of claim 1, wherein a material of the metal layer is selected from a group consisting of Ag, Al, Cu, Cr, Zn, Mo, Ca, Ti, Tn, Sn, Ni, and combination thereof.

8. The process of claim 7, wherein the material of the metal layer is Al.

9. The process of claim 1, wherein a material of the transparent conductive oxide is selected from a group consisting of ZnO, ZnO:Al (AZO), ZnO:Ga(GZO), SnO₂:Sb(ATO), SnO₂:F(FTO), In₂O₃:Sn(ITO), BaTiO and combination thereof.

10. The process of claim 9, wherein the material of the transparent conductive oxide is ZnO.

11. The process of claim 1, wherein the transparent conductive oxide layer has a thickness ranging from 0.05 to 3 μm.

12. The process of claim 1, wherein the metal layer has a thickness ranging from 1 to 1000 nm.

13. The process of claim 1, further comprising a step of forming a barrier layer on the substrate before the step of forming the metal layer.

14. The process of claim 13, wherein the barrier layer is a SiO₂ layer.

15. The process of claim 13, wherein the barrier layer has a thickness ranging from 1 to 100 nm.

16. A TCO substrate with light trapping feature comprising:
a substrate;
a plurality of island-structure metal protrusions, formed on the substrate; and
a TCO layer, formed on the substrate and the island-structure metal protrusions.

17. The TCO substrate of claim 16, wherein the island-structure metal protrusions are semi-spherical metal protrusions.

18. The TCO substrate of claim 16, wherein the TCO layer is a smooth layer formed on the substrate and the island-structure metal protrusions.

19. The TCO substrate of claim 16, wherein the TCO layer is a saw toothed layer.

20. A solar cell comprising a TCO substrate as defined in claim 16.
